(19) United States
(12) Patent Application Publication
(10) Pub. No.: US 2025/0350243 A1
(43) Pub. Date: Nov. 13, 2025

(54) SUB-HARMONIC MIXER MODULE INCLUDING POSITION-ADJUSTABLE GROUND CONDUCTOR AND METHOD FOR MANUFACTURING THE SAME

(71) Applicant: ELECTRONICS AND TELECOMMUNICATIONS RESEARCH INSTITUTE, Daejeon (KR)

(72) Inventors: Young Ho KIM, Daejeon (KR); Dong Woo PARK, Daejeon (KR); Jun-Hwan SHIN, Daejeon (KR)

(73) Assignee: ELECTRONICS AND TELECOMMUNICATIONS RESEARCH INSTITUTE, Daejeon (KR)

(21) Appl. No.: 19/013,347

(22) Filed: Jan. 8, 2025

(30) Foreign Application Priority Data
May 7, 2024 (KR) 10-2024-0059989

(51) Int. Cl. H03D 7/00

(52) U.S. Cl. CPC H03D 7/00

(57) ABSTRACT

Disclosed is a sub-harmonic mixer module including a dielectric circuit unit and a ground conductor. The dielectric circuit unit includes a dielectric substrate, a first conversion probe, a second conversion probe, a nonlinear element, and an RF/DC ground circuit. The first conversion probe converts an RF electromagnetic wave into a first electrical signal. The second conversion probe converts an LO electromagnetic wave into a second electrical signal. The nonlinear element switches depending on the second electrical signal and generates a third electrical signal. The ground conductor is connected with the RF/DC ground circuit and provides ground voltage. The first conversion probe, the second conversion probe, the nonlinear element, and the RF/DC ground circuit are formed on one surface of the dielectric substrate. The ground conductor is disposed to make contact with the one surface of the dielectric substrate and is position-adjustable.

### CROSS-REFERENCE TO RELATED APPLICATIONS

This application claims priority under 35 U.S.C. § 119 to Korean Patent Application No. 10-2024-0059989 filed on May 7, 2024, in the Korean Intellectual Property Office, the disclosure of which is incorporated by reference herein in its entirety.

### BACKGROUND

Embodiments of the present disclosure described herein relate to an electronic device, and more particularly, relate to a sub-harmonic mixer module and a method for manufacturing the sub-harmonic mixer module.

Terahertz waves are electromagnetic waves having a frequency band of about 0.1 THz to about 10 THz. Since the terahertz waves have both electrical characteristics and optical characteristics, the terahertz waves may penetrate non-metallic materials such as paper, plastic, and ceramic, may have very high directivity, and may be harmless to the human body, unlike X-rays.

A sub-harmonic mixer used in the terahertz band may use an Nth (e.g., second) harmonic instead of a local oscillator (LO) fundamental frequency as an LO signal and may generate an intermediate frequency (IF) signal by mixing a radio frequency (RF) signal and the LO signal.

However, when the high-performance sub-harmonic mixer used in the terahertz band is manufactured, various processes are performed, and in particular, when a module is assembled, a random error occurring in an attaching process significantly degrades the performance of the sub-harmonic mixer.

### SUMMARY

Embodiments of the present disclosure provide a sub-harmonic mixer module for eliminating performance degradation, reducing a random error, and tuning electrical characteristics.

Embodiments of the present disclosure provide a method for manufacturing the sub-harmonic mixer module.

According to an embodiment, a sub-harmonic mixer module includes a dielectric circuit unit and a ground conductor unit. The dielectric circuit unit includes a dielectric substrate, a first conversion probe, a second conversion probe, a nonlinear element, and an RF/DC ground circuit. The first conversion probe converts a radio frequency (RF) electromagnetic wave into a first electrical signal. The second conversion probe converts a local oscillator (LO) electromagnetic wave into a second electrical signal. The nonlinear element switches depending on the second electrical signal and generates a third electrical signal. The RF/DC ground circuit provides ground voltage. The ground conductor unit includes a ground conductor. The ground conductor is connected with the RF/DC ground circuit and provides the ground voltage. The first conversion probe, the second conversion probe, the nonlinear element, and the RF/DC ground circuit are formed on one surface of the dielectric substrate. The ground conductor is disposed to make contact with the one surface of the dielectric substrate and is position-adjustable.

According to an embodiment, in a method for manufacturing a sub-harmonic mixer module, a process of manufacturing a dielectric circuit unit is performed. In the process, a first conversion probe, a second conversion probe, and an RF/DC ground circuit are formed on a dielectric substrate, and a nonlinear element is bonded to the dielectric substrate. a process of aligning the dielectric circuit unit with a metal housing and bonding the dielectric circuit unit to the metal housing is performed. The position of a ground conductor on the dielectric substrate is adjusted. The ground conductor is connected with the RF/DC ground circuit. The ground conductor is brought into contact with one surface of the dielectric substrate.

### BRIEF DESCRIPTION OF THE FIGURES

The above and other objects and features of the present disclosure will become apparent by describing in detail embodiments thereof with reference to the accompanying drawings.

FIG. 1 is a perspective view illustrating part of a sub-harmonic mixer module according to an embodiment of the present disclosure.

FIG. 2 is a view for explaining position-adjustment of a ground conductor of FIG. 1.

FIG. 3 is a view for explaining a radio frequency (RF)/direct current (DC) ground circuit of FIG. 1.

FIG. 4 is a view for explaining a fine movement adjustment part included in the sub-harmonic mixer module or the ground conductor unit of FIG. 1.

FIGS. 5 and 6 are views for explaining an arrangement of the ground conductor of FIG. 1.

FIG. 7 is a flowchart illustrating a method for manufacturing the sub-harmonic mixer module according to an embodiment of the present disclosure.

FIG. 8 is a flowchart illustrating an embodiment of a process of adjusting the position of the ground conductor in FIG. 7.

FIG. 9 is a flowchart illustrating an embodiment of a process of placing the ground conductor in FIG. 7.

FIGS. 10A and 10B are views for explaining functions of the RF/DC ground circuit and the ground conductor of FIG. 1.

### DETAILED DESCRIPTION

Hereinafter, embodiments of the present disclosure will be described clearly and in detail to such an extent that those skilled in the art easily implement the present disclosure.

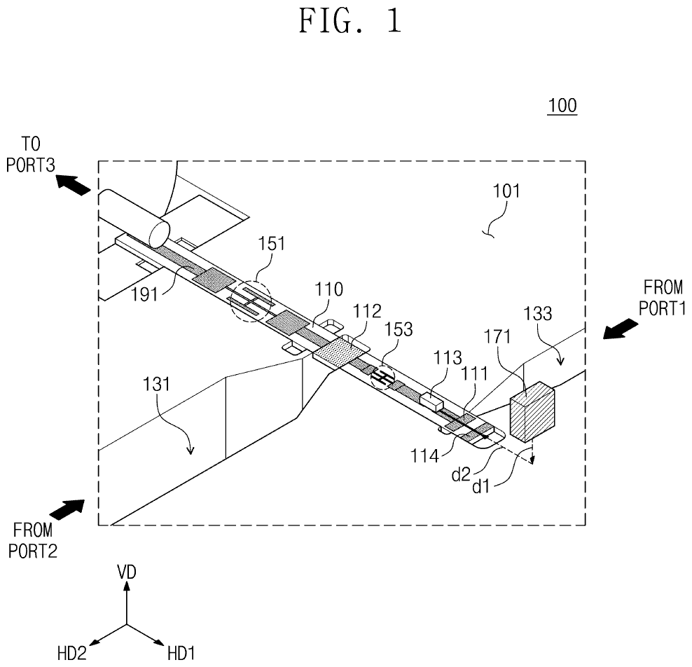

FIG. 1 is a perspective view illustrating part of a sub-harmonic mixer module according to an embodiment of the present disclosure.

In FIG. 1, a first horizontal direction HD1, a second horizontal direction HD2, and a vertical direction VD perpendicular to one another are illustrated, and in the following descriptions, the directions HD1, HD2, and VD may be uniformly used.

Referring to FIG. 1, the sub-harmonic mixer module 100 may include a dielectric circuit unit and a ground conductor unit. The dielectric circuit unit may include a dielectric substrate 110, a first conversion probe 111, a second conversion probe 112, a nonlinear element 113, and a radio frequency (RF)/direct current (DC) ground circuit 114. The ground conductor unit may include a ground conductor 171. In an embodiment, the sub-harmonic mixer module 100 may generate an intermediate frequency (IF) signal by mixing an RF signal and a local oscillator (OL) signal and may be used in the terahertz band.

The dielectric substrate 110 may include, for example, quartz. The first conversion probe 111 may convert an RF electromagnetic wave into a first electrical signal, and the second conversion probe 112 may convert an LO electromagnetic wave into a second electrical signal. The nonlinear element 113 may switch depending on the second electrical signal and may generate a third electrical signal, and the RF/DC ground circuit 114 may provide ground voltage. The ground conductor 171 may be connected with the RF/DC ground circuit 114 and may provide the ground voltage.

In an embodiment, the sub-harmonic mixer module 100 may further include a first port PORT1 that receives the RF electromagnetic wave, a first wave guide 133 that transfers the RF electromagnetic wave transferred through the first port PORT1 to the first conversion probe 111, a second port PORT2 that receives the LO electromagnetic wave, a second wave guide 131 that transfers the LO electromagnetic wave transferred through the second port PORT2 to the second conversion probe 112, and a third port PORT3 that outputs the third electrical signal passing through a metal line 191. For example, the first port PORT1 may be referred to as an “RF port”, the second port PORT2 may be referred to as an “LO port”, and the third port PORT3 may be referred to as an “IF port”.

In an embodiment, the dielectric circuit unit may further include a first filter circuit 153 that filters the first electrical signal and a second filter circuit 151 that filters the first electrical signal and the second electrical signal. For example, the first filter circuit 153 may be used to prevent leakage of components of the first electrical signal to the second port PORT2 (or, the LO port), and the second filter circuit 151 may be used to prevent leakage of the first electrical signal, the second electrical signal, and harmonic components thereof to the third port PORT3 (or, the IF port).

In an embodiment, the nonlinear element 113 may be used to generate, for example, an Nth (e.g., second) harmonic from an LO fundamental frequency when the sub-harmonic mixer module 100 is used in the terahertz band. For example, the nonlinear element 113 may include a Schottky barrier diode AP-SBD in an anti-parallel form, and the AP-SBD may have low internal capacitance and low internal series resistance and may provide a high cutoff frequency accordingly. For example, the nonlinear element 113 may switch depending on the second electrical signal and may generate the third electrical signal frequency-mixed with the first electrical signal.

In an embodiment, the RF/DC ground circuit 114 may provide a DC current path of the sub-harmonic mixer module 100, may operate to appear as an open circuit from the perspective of the first electrical signal, and may provide an alternating current (AC) ground reference point from the perspective of the second electrical signal. For example, the RF/DC ground circuit 114 may provide a very large resistance value at an open level for the first electrical signal, may provide a very small resistance value at a short level for the second electrical signal, and may provide the ground voltage for a direct current (DC) voltage/current.

In an embodiment, the sub-harmonic mixer module 100 may be implemented with a plurality of metal housings including a lower metal housing and an upper metal housing. For example, in FIG. 1, the lower metal housing 101 including the first wave guide 133 and the second wave guide 131 may be prepared, the dielectric substrate 110 may be mounted on the lower metal housing 101, and the plurality of circuits 111, 112, 113, 114, 151, and 153 of the sub-harmonic mixer module 100 may be mounted on the dielectric substrate 110. Thereafter, the upper metal housing may be coupled to the lower metal housing 101.

In an embodiment, the ground conductor 171 may have a three-dimensional structure shape. The ground conductor 171 may be disposed to make contact with one surface of the dielectric substrate 110 and may be position-adjustable. For example, by moving in the vertical direction VD by a distance (e.g., d1) and moving in the direction opposite to the first horizontal direction HD1 by a distance (e.g., d2), the ground conductor 171 may be disposed to make contact with the RF/DC ground circuit 114. For example, the ground conductor 171 may be connected with the plurality of metal housings and may provide the ground voltage to the RF/DC ground circuit 114.

According to the above-described configuration, the sub-harmonic mixer module 100 according to embodiments of the present disclosure may stably provide the very large resistance value at the open level, the very small resistance value at the short level, or the ground voltage to the RF/DC ground circuit 114 using the ground conductor 171 connected with the metal housings. Since the ground conductor 171 has a three-dimensional structure shape and is position-adjustable, the ground conductor 171 may be precisely brought into contact with a desired location of the RF/DC ground circuit 114, and even when a plurality of sub-harmonic mixer modules are manufactured, each of the sub-harmonic mixer modules may have the same electrical characteristics and may reduce a random error. In addition, since the ground conductor 171 is position-adjustable even after the sub-harmonic mixer module 100 is manufactured, the electrical characteristics of the sub-harmonic mixer module 100 may be tuned, and thus the sub-harmonic mixer module 100 may exhibit stable, excellent, and optimized performance.

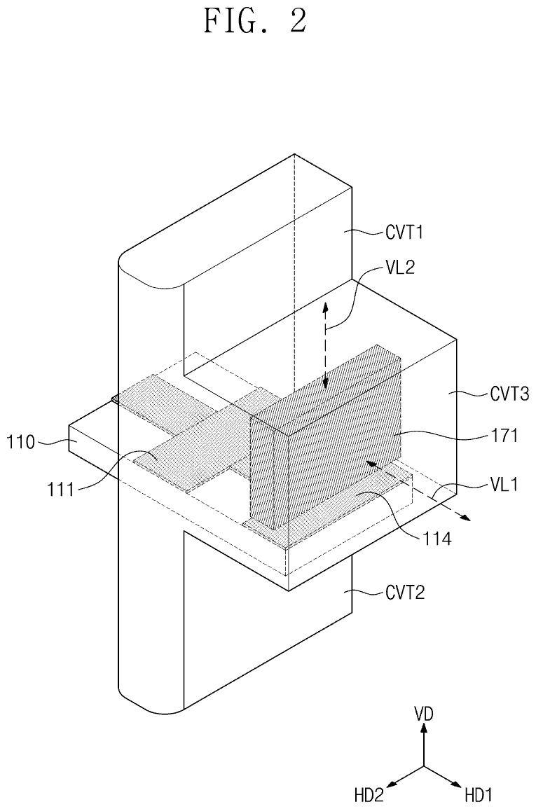

FIG. 2 is a view for explaining position-adjustment of the ground conductor of FIG. 1.

Referring to FIGS. 1 and 2, components having the same reference numerals may perform the same or similar functions. In FIG. 2, for convenience of description, only the dielectric substrate 110, the first conversion probe 111, the RF/DC ground circuit 114, and the ground conductor 171 among the components of FIG. 1 are illustrated.

In an embodiment, each of the plurality of metal housings described above with reference to FIG. 1 includes an empty space. For example, the upper metal housing includes an empty space CVT1 and an empty space CVT3, and the lower metal housing includes an empty space CVT2 and the empty space CVT3. For example, the ground conductor 171 may be position-adjustable in the empty space CVT3.

In an embodiment, the ground conductor 171 may be position-adjustable along a virtual first line VL1 or a virtual second line VL2. For example, the first line VL1 may be parallel to the one surface of the dielectric substrate 110, and the second line VL2 may be perpendicular to the one surface of the dielectric substrate 110. For example, the first line VL1 may correspond to the first horizontal direction HD1, and the second line VL2 may correspond to the second horizontal direction VD. For example, the first line VL1 may correspond to a virtual line along which the first conversion probe 111, the second conversion probe 112, the nonlinear element 113, and the RF/DC ground circuit 114 of FIG. 1 are disposed, but the spirit and scope of the present disclosure is not limited thereto.

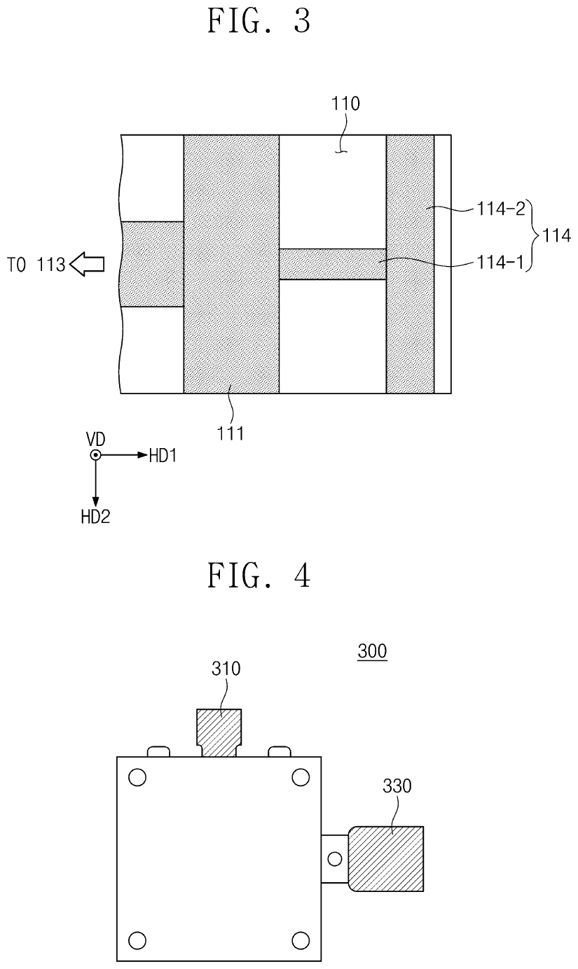

FIG. 3 is a view for explaining the radio frequency (RF)/direct current (DC) ground circuit of FIG. 1.

Referring to FIGS. 1, 2, and 3, the first conversion probe 111 may be connected with the nonlinear element 113, and the RF/DC ground circuit 114 may be connected with the first conversion probe 111.

As described above with reference to FIG. 1, the ground conductor 171 may be disposed to make contact with the RF/DC ground circuit 114. In an embodiment, the RF/DC ground circuit 114 may include only a first transmission line 114-1 or may include both the first transmission line 114-1 and a second transmission line 114-2. For example, the first transmission line 114-1 may extend along the virtual first line VL1 of FIG. 2 (e.g., HD1), and the second transmission line 114-2 may extend in a direction perpendicular to the extension direction of the first transmission line 114-1 (e.g., HD2).

In an embodiment, the RF/DC ground circuit 114 may include only the first transmission line 114-1. In this case, the ground conductor 171 may be disposed to make contact with the first transmission line 114-1. However, the spirit and scope of the present disclosure is not limited thereto.

In an embodiment, the RF/DC ground circuit 114 may include both the first transmission line 114-1 and the second transmission line 114-2. In this case, the ground conductor 171 may be disposed to make contact with the second transmission line 114-2. However, the spirit and scope of the present disclosure is not limited thereto.

FIG. 4 is a view for explaining a fine movement adjustment part included in the sub-harmonic mixer module or the ground conductor unit of FIG. 1.

Referring to FIGS. 1 and 4, the sub-harmonic mixer module 100 or the ground conductor unit may further include the fine movement adjustment part 300. The fine movement adjustment part 300 may adjust the position of the ground conductor 171 along a virtual first line (e.g., the virtual first line VL1 of FIG. 2) or a virtual second line (e.g., the virtual second line VL2 of FIG. 2).

In an embodiment, the fine movement adjustment part 300 may include a first adjustment screw 310 for adjusting the position of the ground conductor 171 along the first line and a second adjustment screw 320 for adjusting the position of the ground conductor 171 along the second line. However, the spirit and scope of the present disclosure is not limited thereto.

In an embodiment, as described above with reference to FIG. 2, the plurality of metal housings may contain the dielectric circuit unit and the ground conductor unit of FIG. 1, and the fine movement adjustment part 300 may be disposed on the outer surface of the upper metal housing among the plurality of metal housings. However, the spirit and scope of the present disclosure is not limited thereto.

In an embodiment, as described above with reference to FIG. 2, the ground conductor 171 may be position-adjustable in the empty space CVT3, and the fine movement adjustment part 300 may adjust the position of the ground conductor 171 in the empty space CVT3 using the first adjustment screw 310 and the second adjustment screw 330.

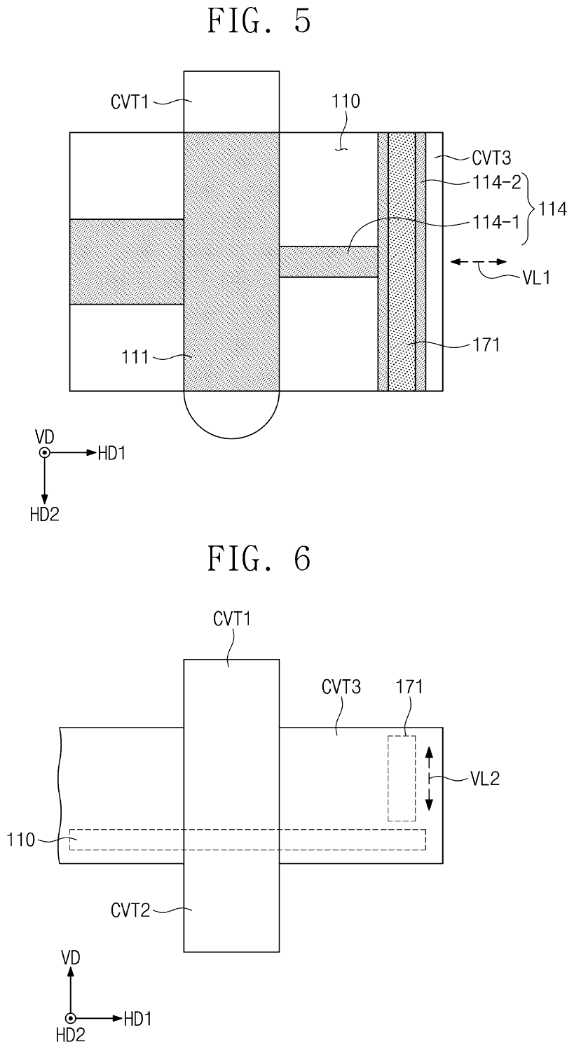

FIGS. 5 and 6 are views for explaining an arrangement of the ground conductor of FIG. 1.

Referring to FIGS. 1 to 3, 5, and 6, components having the same reference numerals may perform the same or similar functions.

As illustrated in FIG. 5, the ground conductor 171 may be position-adjustable along the virtual first line VL1 and may be disposed to make contact with a portion of the second transmission line 114-2 of the RF/DC ground circuit 114. However, the spirit and scope of the present disclosure is not limited thereto. In an embodiment, the ground conductor 171 may have a three-dimensional structure shape with a first width, a first length, and a first height. Alternatively, the shape of the ground conductor 171 may be changed, and the ground conductor 171 may be disposed to make contact with all or part of the second transmission line 114-2. In an embodiment, when the ground conductor 171 includes only the first transmission line 114-1, the ground conductor 171 may be disposed to make contact with all or part of the first transmission line 114-1.

As illustrated in FIG. 6, the ground conductor 171 may be position-adjustable along the virtual second line VL2, and after the ground conductor 171 is located on the RF/DC ground circuit 114 as illustrated in FIG. 5, the ground conductor 171 may be moved along the second line VL2 to make contact with the RF/DC ground circuit 114.

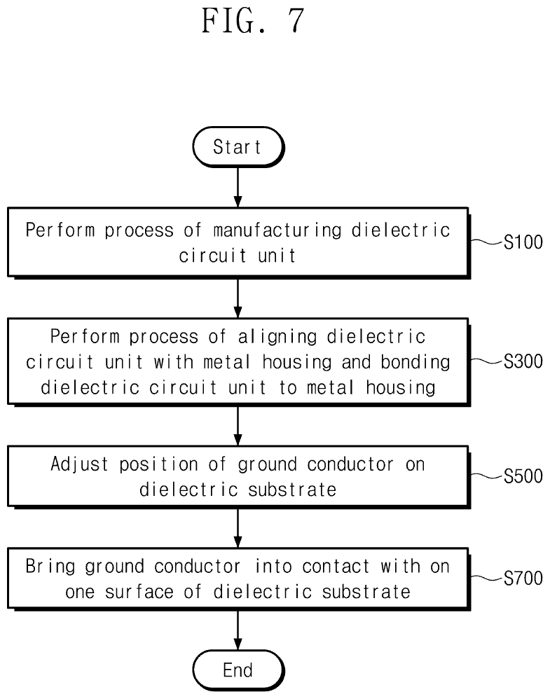

FIG. 7 is a flowchart illustrating a method for manufacturing the sub-harmonic mixer module according to an embodiment of the present disclosure.

Referring to FIG. 7, a process of manufacturing the dielectric circuit unit may be performed (S100).

For example, the first conversion probe, the second conversion probe, and the RF/DC ground circuit may be formed on the dielectric substrate through a process. For example, the process of manufacturing the dielectric circuit unit may be performed by forming the first conversion probe, the second conversion probe, and the RF/DC ground circuit on the dielectric substrate and then bonding the nonlinear element to the dielectric substrate in a flip-chip form.

A process of aligning the dielectric circuit unit with the metal housing and bonding the dielectric circuit unit to the metal housing may be performed (S300).

The ground conductor may be position-adjustable on the dielectric substrate (S500).

The ground conductor may be disposed to make contact with the one surface of the dielectric substrate (S700).

In an embodiment, the first filter circuit and the second filter circuit may be additionally formed on the dielectric substrate.

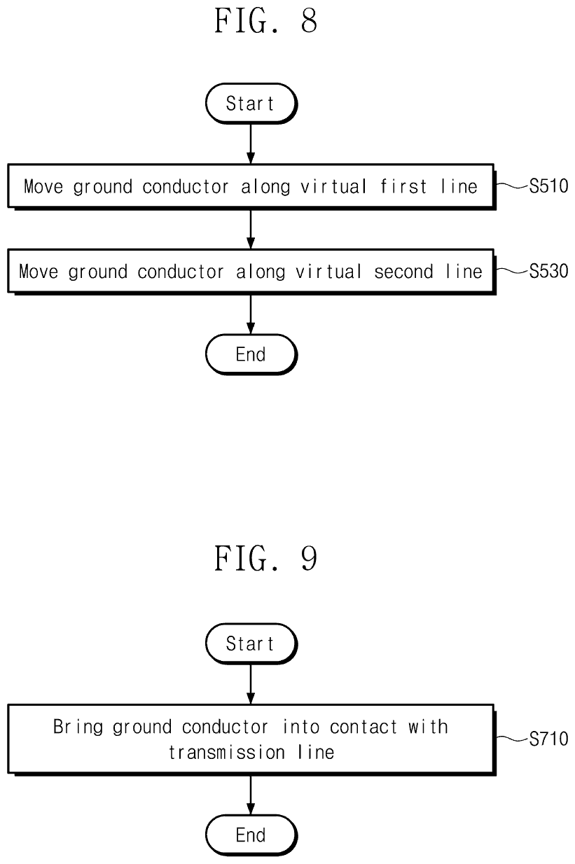

FIG. 8 is a flowchart illustrating an embodiment of the process of adjusting the position of the ground conductor in FIG. 7.

Referring to FIGS. 7 and 8, in the process of adjusting the position of the ground conductor on the dielectric substrate, the ground conductor may be moved along the virtual first line parallel to the one surface of the dielectric substrate (S510).

The ground conductor may be moved along the virtual second line perpendicular to the one surface of the dielectric substrate (S530).

FIG. 9 is a flowchart illustrating an embodiment of the process of placing the ground conductor in FIG. 7.

Referring to FIGS. 7 and 9, in the process in which the ground conductor is disposed to make contact with the one surface of the dielectric substrate, the ground conductor may be disposed to make contact with the transmission lines (S710).

In an embodiment, the RF/DC ground circuit may include, on the dielectric substrate, the first transmission line extending along the virtual first line, and in the process in which the ground conductor is disposed to make contact with the one surface of the dielectric substrate, the ground conductor may be disposed to make contact with the first transmission line.

In an embodiment, the RF/DC ground circuit may further include, on the dielectric substrate, the second transmission line that is connected with the first transmission line and that extends in the direction perpendicular to the extension direction of the first transmission line, and in the process in which the ground conductor is disposed to make contact with the one surface of the dielectric substrate, the ground conductor may be disposed to make contact with the second transmission line instead of the first transmission line.

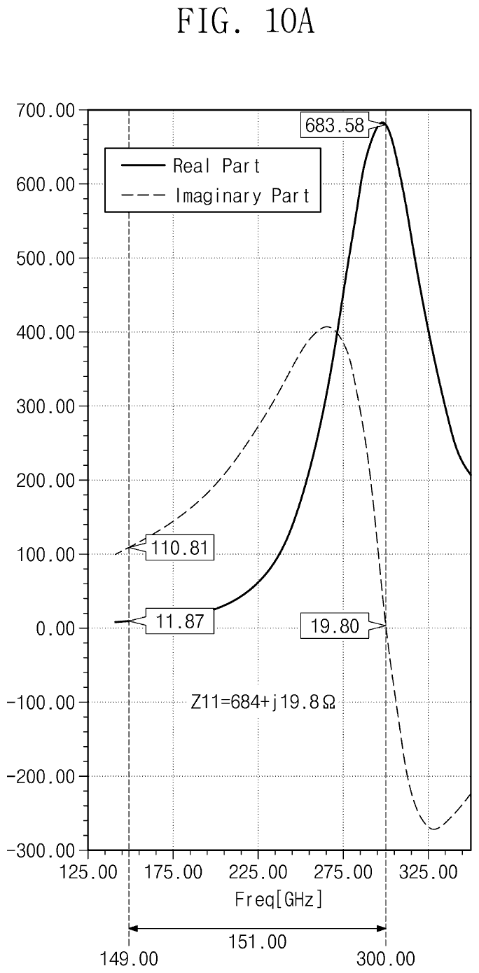

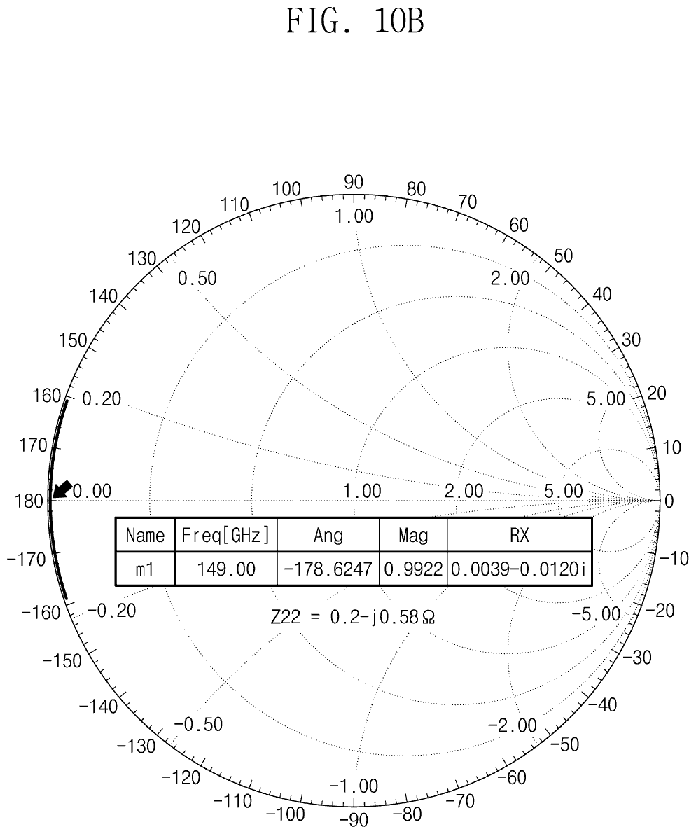

FIGS. 10A and 10B are views for explaining functions of the RF/DC ground circuit and the ground conductor of FIG. 1.

Referring to FIGS. 1 and 10A, an example of an electromagnetic (EM) simulation result regarding impedance characteristics when the RF/DC ground circuit 114 is viewed from a boundary node of the first conversion probe 111 is illustrated.

According to the simulation result, the impedance parameter Z11 represents 683.58 ohms (Ω) at 300 GHz, which is a sufficiently large value. Accordingly, the first electrical signal received through the RF port and converted through the first conversion probe 111 may flow into the impedance-matched nonlinear element 113.

Referring to FIGS. 1 and 10B, a node on the first conversion probe 111 side is set to port-1, a node on the nonlinear element 113 side is set to port-2, and an example of an electromagnetic (EM) simulation result regarding impedance characteristics when the RF/DC ground circuit 114 is viewed from a node of the nonlinear element 113 connected to the first conversion probe 111 side is illustrated.

When the design frequency of the LO signal is set to 149 GHz, values in the band near 149 GHz may be considered as almost a short on the Smith chart, and since the node on the nonlinear element 113 side has a low impedance of about 0.2-j0.58Ω, the nonlinear element 113 may stably and efficiently switch for the LO signal.

As described above with reference to FIG. 1, the RF/DC ground circuit 114 may provide the DC current path of the sub-harmonic mixer module 100, may operate to appear as an open circuit from the perspective of the first electrical signal, and may provide the AC ground reference point from the perspective of the second electrical signal.

As described above, the sub-harmonic mixer module according to the embodiments of the present disclosure may stably provide the ground voltage while providing impedance for each frequency (e.g., a very large resistance value at an open level or a very small resistance value at a short level) required for the operation of the mixer circuit by using the ground conductor, which is connected to the metal housings, for the RF/DC ground circuit. Since the ground conductor has a three-dimensional structure shape and is position-adjustable, the ground conductor may be precisely brought into contact with a desired location of the RF/DC ground circuit, and even when a plurality of sub-harmonic mixer modules are manufactured, each of the sub-harmonic mixer modules may have the same electrical characteristics and may reduce a random error. In addition, since the ground conductor is position-adjustable even after the sub-harmonic mixer module is manufactured, the electrical characteristics of the sub-harmonic mixer module may be tuned, and thus the sub-harmonic mixer module may exhibit stable, excellent, and optimized performance.

The sub-harmonic mixer module according to the embodiments of the present disclosure may stably provide the ground voltage while providing impedance for each frequency (e.g., a very large resistance value at an open level or a very small resistance value at a short level) required for the operation of the mixer circuit by using the ground conductor, which is connected to the metal housings, for the RF/DC ground circuit. Since the ground conductor has a three-dimensional structure shape and is position-adjustable, the ground conductor may be precisely brought into contact with a desired location of the RF/DC ground circuit, and even when a plurality of sub-harmonic mixer modules are manufactured, each of the sub-harmonic mixer modules may have the same electrical characteristics and may reduce a random error. In addition, since the ground conductor is position-adjustable even after the sub-harmonic mixer module is manufactured, the electrical characteristics of the sub-harmonic mixer module may be tuned, and thus the sub-harmonic mixer module may exhibit stable, excellent, and optimized performance.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A sub-harmonic mixer module comprising:
a dielectric circuit unit; and
a ground conductor unit,
wherein the dielectric circuit unit includes:
a dielectric substrate;
a first conversion probe configured to convert a radio frequency (RF) electromagnetic wave into a first electrical signal;
a second conversion probe configured to convert a local oscillator (LO) electromagnetic wave into a second electrical signal;
a nonlinear element configured to switch depending on the second electrical signal and generate a third electrical signal; and
a radio frequency RF/direct current (DC) ground circuit configured to provide ground voltage,
wherein the ground conductor unit includes a ground conductor connected with the RF/DC ground circuit and configured to provide the ground voltage,
wherein the first conversion probe, the second conversion probe, the nonlinear element, and the RF/DC ground circuit are formed on one surface of the dielectric substrate, and
wherein the ground conductor is disposed to make contact with the one surface of the dielectric substrate and is position-adjustable.

2. The sub-harmonic mixer module of claim 1, wherein the first conversion probe, the second conversion probe, the nonlinear element, and the RF/DC ground circuit are disposed along a virtual first line, and
wherein the ground conductor is located on the RF/DC ground circuit and is position-adjustable along the virtual first line.

3. The sub-harmonic mixer module of claim 2, wherein the ground conductor is located on the RF/DC ground circuit and is further position-adjustable along a virtual second line perpendicular to the one surface of the dielectric substrate.

4. The sub-harmonic mixer module of claim 3, wherein the ground conductor unit further includes a fine movement adjustment part configured to adjust the position of the ground conductor along the virtual first line or the virtual second line.

5. The sub-harmonic mixer module of claim 4, wherein the fine movement adjustment part includes:
a first adjustment screw configured to adjust the position of the ground conductor along the virtual first line; and
a second adjustment screw configured to adjust the position of the ground conductor along the virtual second line.

6. The sub-harmonic mixer module of claim 4, further comprising:
a metal housing configured to contain the dielectric circuit unit and the ground conductor unit.

7. The sub-harmonic mixer module of claim 6, wherein the fine movement adjustment part is disposed on an outer surface of the metal housing.

8. The sub-harmonic mixer module of claim 7, wherein the metal housing includes an empty space, and
wherein the ground conductor is position-adjustable in the empty space by the fine movement adjustment part.

9. The sub-harmonic mixer module of claim 2, wherein the RF/DC ground circuit includes, on the dielectric substrate, a first transmission line configured to extend along the virtual first line.

10. The sub-harmonic mixer module of claim 9, wherein the ground conductor is disposed to make contact with the first transmission line.

11. The sub-harmonic mixer module of claim 9, wherein the RF/DC ground circuit further includes, on the dielectric substrate, a second transmission line connected with the first transmission line and configured to extend in a direction perpendicular to an extension direction of the first transmission line.

12. The sub-harmonic mixer module of claim 11, wherein the ground conductor is disposed to make contact with the second transmission line.

13. The sub-harmonic mixer module of claim 1, wherein the ground conductor has a three-dimensional structure shape with a first width, a first length, and a first height.

14. The sub-harmonic mixer module of claim 1, wherein the dielectric circuit unit further includes:
a first filter circuit configured to filter the first electrical signal; and
a second filter circuit configured to filter the first electrical signal and the second electrical signal.

15. The sub-harmonic mixer module of claim 14, further comprising:
a first port configured to receive the RF electromagnetic wave;
a second port configured to receive the LO electromagnetic wave;
a third port configured to output the third electrical signal;
a first wave guide configured to transfer the RF electromagnetic wave to the first conversion probe; and
a second wave guide configured to transfer the LO electromagnetic wave to the second conversion probe.

16. A method for manufacturing a sub-harmonic mixer module, the method comprising:
performing a process of manufacturing a dielectric circuit unit by forming a first conversion probe, a second conversion probe, and an RF/DC ground circuit on a dielectric substrate and bonding a nonlinear element to the dielectric substrate;
performing a process of aligning the dielectric circuit unit with a metal housing and bonding the dielectric circuit unit to the metal housing;
adjusting the position of a ground conductor on the dielectric substrate, the ground conductor being connected with the RF/DC ground circuit; and
bringing the ground conductor into contact with one surface of the dielectric substrate.

17. The method of claim 16, wherein the adjusting the position of the ground conductor on the dielectric substrate includes:
moving the ground conductor along a virtual first line parallel to the one surface of the dielectric substrate; and
moving the ground conductor along a virtual second line perpendicular to the one surface of the dielectric substrate.

18. The method of claim 17, wherein the RF/DC ground circuit includes, on the dielectric substrate, a first transmission line configured to extend along the virtual first line, and
wherein the bringing the ground conductor into contact with the one surface of the dielectric substrate includes a bringing the ground conductor into contact with the first transmission line.

19. The method of claim 18, wherein the RF/DC ground circuit further includes, on the dielectric substrate, a second transmission line connected with the first transmission line and configured to extend in a direction perpendicular to an extension direction of the first transmission line, and
wherein the bringing the ground conductor into contact with the one surface of the dielectric substrate includes a bringing the ground conductor into contact with the second transmission line instead of the first transmission line.

20. The method of claim 16, further comprising:
forming a first filter circuit and a second filter circuit on the dielectric substrate in the process of manufacturing the dielectric circuit unit.
